(19) United States
(12) Patent Application Publication
(10) Pub. No.: US 2022/0151105 A1
(43) Pub. Date: May 12, 2022

(54) COOLING DEVICE FOR AN OBJECT DETECTION SENSOR

(71) Applicant: Ibeo Automotive Systems GmbH, Hamburg (DE)

(72) Inventors: Stefan Hakspiel, Tettnang (DE); Simon FRICK, Wilhelmsdorf (DE)

(73) Assignee: Ibeo Automotive Systems GmbH, Hamburg (DE)

(21) Appl. No.: 17/426,006

(22) PCT Filed: Jan. 27, 2020
(86) PCT No.: PCT/EP2020/051926

§ 371 Date: Jul. 28, 2021

(30) Foreign Application Priority Data
Jan. 28, 2019 (DE) 10 2019 201 031.8

(51) Int. Cl. H05K 7/20; H05K 5/02

(52) U.S. Cl. CPC H05K 7/20436; H05K 5/0204

(57) ABSTRACT

A cooling device for an object detection sensor, having a sensor-side heat transmission element, a sensor-distant heat absorption element, wherein the sensor-side heat transmission element and the sensor-distant heat absorption element are arranged opposite to one another, wherein a heat transmission surface of the sensor-distant heat transmission element and a heat absorption surface of the sensor-distant heat absorption element are designed to be spaced apart from one another by an intermediate space. Furthermore, an object detection sensor including such a cooling device is described.

The invention relates to a cooling device for an object detection sensor.

Object detection sensors, such as radar and lidar systems or also cameras are increasingly used in motor vehicles to examine the environment of the vehicle for objects. In most cases, a relative position and a relative speed are determined with respect to the object detection sensor and thus also to the motor vehicle. Such object detection sensors generate during operation a significant amount of heat energy which must be dissipated.

From U.S. Pat. No. 3,844,341 a heat transmission device is known comprising a first part and a second part which are continuously rotatable relative to one another clockwise or counterclockwise.

It is therefore an object of the invention to provide a cooling device for an object detection sensor that provides reliable and effective cooling of the object detection sensor.

This object is achieved by a cooling device according to patent claim 1. The dependent patent claims represent advantageous embodiment variants of the cooling device.

An object detection sensor can be formed, for example, by a radar system, a lidar system or a camera system.

Radar and lidar systems comprise a transmitting element, which emits electromagnetic radiation, and at least one detecting element, which detects the radiation previously emitted and reflected at an object. By evaluating the measurement data determined by the detection element, a relative position of objects and, in most cases, a relative speed with respect to the object detection sensor is determined.

Camera systems mostly comprise only one detection element which detects incoming radiation from the environment in order to display a camera image. Where appropriate, a camera system can also comprise a transmitting element, such as an infrared lamp.

Such object detection sensors are used in motor vehicles to provide driving assistance functions, semi-autonomous driving functions or fully autonomous driving functions. However, the field of application is not exclusively limited to motor vehicles but can also be used for all other types of vehicles. Stationary use is also possible.

The cooling device is designed in particular for such an object detection sensor. The cooling device comprises a sensor-side heat transmission element and a sensor-distant heat absorption element. The sensor-side heat transmission element and the sensor-distant heat absorption element are arranged opposite to one another. In this case, a heat transmission surface of the sensor-side heat transmission element and a heat absorption surface of the sensor-distant heat absorption element are designed to be spaced apart from one another by an intermediate space.

The cooling device is designed to provide a relative movement between the heat transmission element and the heat absorption element.

Such a relative movement is accompanied by a relative movement performed by the object detection sensor. Accordingly, the heat transmission element attached to or formed by the object detection sensor performs a joint movement with the object detection sensor. In particular, such relative movement is a pivoting movement. This movement can provide a pivot range of a few degrees, for example, pivot angles between 5° to 20° are possible. Such a pivoting process enables the object detection sensor to cover a larger angular range. As a result, a viewing direction of the object detection sensor can be changed, for example.

The sensor-side heat transmission element is in contact with or formed on the heat-generating object detection sensor. In particular, heat generated by electronic components of the object detection sensor, such as a transmitting element in the form of a transmitting chip, and/or a receiving element in the form of a receiving chip, is transmitted to the heat transmission element. Accordingly, the heat transmission element heats up and transmits the introduced heat energy, in particular by radiant heat, to the sensor-distant heat absorption element via the intermediate space. The sensor-distant heat absorption element absorbs this thermal radiation and dissipates it to an environment.

By such an embodiment, the object detection sensor can be designed to be rotatable or at least pivotable within a certain angular range while an effective dissipation of the generated heat is still provided.

The heat transmission surface is advantageously fixedly connected to the object detection sensor, in particular to a sensor housing of the object detection sensor and performs a joint movement therewith. The heat absorption element is advantageously fixedly connected to an environmental element with respect to which the object detection sensor and also the heat transmission element can move. In particular, this environmental element is formed by a module housing which encloses the object detection sensor and also the cooling device.

Due to the intermediate space, a free pivoting movement can be provided relative to a cooling device which establishes mechanical contact between the heat transmission element and the heat absorption element. This is made possible because the heat transmission surface and the heat absorption surface do not come into abutting contact and thus a free relative movement, in particular frictionless relative movement, is made possible.

In the following, advantageous embodiment variants of the invention are explained.

Particularly advantageously, the heat transmission element is formed by a sensor housing of the object detection sensor or is connected to a sensor housing of the object detection sensor.

The sensor housing is a housing of the object detection sensor that encloses or surrounds the components of the object detection sensor. In particular, the sensor housing comprises a transmitting element, a receiving element and/or a circuit board with electronics. Advantageously, the sensor housing is made of aluminum. In the case of a lidar system, the sensor housing can also have an optical transmitting system and/or an optical receiving system.

In a first variant, the sensor housing forms the heat transmission element. Thus, the heat transmission element is an integral part of the sensor housing, with the sensor housing accordingly providing the heat transmission surface. This allows the heat transmission element to come into direct abutting contact with at least a portion of the heat-generating components, thereby enabling optimum dissipation of the heat energy. In particular, the heat transmission element closes off the sensor housing.

Alternatively, the heat transmission element is firmly connected to the housing. Accordingly, it is attached to an already closed sensor housing. The attachment can be made, for example, by means of a screw connection.

In a further variant, the heat absorption element is formed by a holding element or is connected to a holding element.

The holding element can be formed, for example, as a holder for the object detection sensor, wherein the object detection sensor can move, in particular rotate or pivot, relative to the holding element. For providing such a relative movement, the holding element has corresponding holding means, such as one or more bearing elements. The holding element itself is arranged, for example, on a housing of another assembly, in particular on another assembly of a motor vehicle. Preferably, the holding element is attached to a module housing of the object detection sensor or is integrally formed by the module housing. In a one-piece configuration, the corresponding module housing or the housing of the assembly provides one or more structures that provide such a holding function for the object detection sensor.

The heat absorption element can thus be formed by the holding element itself or it is formed by a separate element which is preferably fixedly connected to the holding element. Accordingly, the holding element provides the heat absorption surface, or the heat absorption element fixed to the holding element provides the heat absorption surface.

Preferably, the module housing encloses the object detection sensor and the cooling device. Particularly advantageously, the module housing is sealed in a liquid and gas tight manner.

Particularly advantageously, the heat transmission element and the heat absorption element are spaced apart from one another in each relative position so that there is no abutting contact between them.

This allows a free and low-friction relative movement between the heat transmission element and the heat absorption element. Accordingly, due to the interaction of the heat absorption element and the heat transmission element, no stop is formed to limit the relative movement.

It is proposed that the heat transmission element and/or the heat absorption element have ribs.

Such ribs increase the heat transmission surfaces as well as a heat absorption surface compared to a flat surface. Depending on the design of the ribs, the surface area can increase by a multiple. The ribs are preferably formed integrally by the heat transmission element and/or the heat absorption element.

In a further embodiment variant, the ribs of the heat transmission element and the ribs of the opposite heat absorption element engage with each other.

This can be done in such a manner that between two ribs of the one element, one rib of the other element engages. The engagement can be carried out in a comb-like manner, for example.

Advantageously, the ribs also overlap in a direction R extending from the heat absorption element to the heat transmission element. In particular, in the direction R, one rib of the heat transmission element overlaps with one rib of the opposite heat absorption element. Advantageously, multiple ribs of the respective elements overlap in the direction R. Due to the ribs engaging with one another, heat transmission undersurfaces and heat absorption undersurfaces are provided, wherein a heat transmission undersurface and a heat absorption undersurface are opposite one another and enable an optimized heat exchange. On the one hand, this provides large surface areas and, on the other hand, enables small distances between the surfaces.

A surface normal of such a heat transmission undersurface as well as of a heat absorption undersurface is formed particularly advantageously perpendicular to the direction R and also perpendicular to a pivoting direction. This allows the ribs to engage with their surfaces in a substantially comb-shaped manner, wherein free pivoting over a large angular range is made possible.

It is further proposed that a free space is formed between two adjacent ribs of the transmission element or the heat absorption element, in which free space a rib of the opposite heat absorption element or heat transmission element engages.

In particular, this provides a large overlap of heat transmission surface and heat absorption surface.

The heat transmission element and/or the heat absorption element are advantageously made from a metal, in particular from aluminum.

In an advantageous embodiment, the intermediate space is filled with a heat-conducting fluid.

Accordingly, a free space formed between the ribs is particularly preferably also filled with such a fluid. A fluid can be gaseous or liquid. In particular, air, grease or oil are suitable. Fluids with high thermal conductivity at low viscosity are preferred. When gases are used, in addition to the transfer of heat energy by thermal radiation, a portion is also transferred by convection. When a liquid is used, the transfer of heat energy mainly takes place by thermal conduction of the liquid. When using a liquid, for example, an intermediate space can be sealed off from the outside via a separating element. The liquid is kept inside the intermediate space by the separating element.

It is further proposed that the heat transmission element is in abutting contact with a circuit board and/or a chip of the detection sensor.

This is advantageous if the heat transmission element forms part of the sensor housing or closes off the sensor housing. As a result, direct abutting contact between the heat transmission element and the heat-generating components can be provided. In particular, a heat conduction paste is arranged between them, which enables fast and effective heat transfer. This enables a particularly effective dissipation of the generated heat energy.

Advantageously, the heat transmission surface has a surface optimized for emission and/or the sensor-distant heat transmission surface has a surface optimized for absorption.

The surfaces of the two elements can be identical or different. Such emission-optimized and absorption-optimized surfaces can be provided, for example, by coatings, varnishes or surface treatments.

In an advantageous embodiment variant, the distance between the heat transmission element and the heat absorption element or the heat transmission surface and the heat transmission surface is designed to be less than or equal to 2 millimeters, 1 millimeter or 0.5 millimeters.

By a distance of a few millimeters, the effectiveness of heat transfer is increased. Here, the distance is preferably formed across surface areas, in particular at the engaging ribs.

It is proposed that the heat-conducting fluid is a gas and that the cooling device has a fan for circulating the fluid.

By means of such a fan, a heat transfer provided by convention can be increased.

The object formulated at the beginning is further achieved by an object detection sensor comprising a cooling device according to any one of claims 1 to 11 or by a cooling device according to at least one of the previously explained embodiments. The preceding and further following embodiments relate to such an object detection sensor.

The cooling device and the object detection sensor are explained in detail by way of example with reference to several figures.

In the figures:

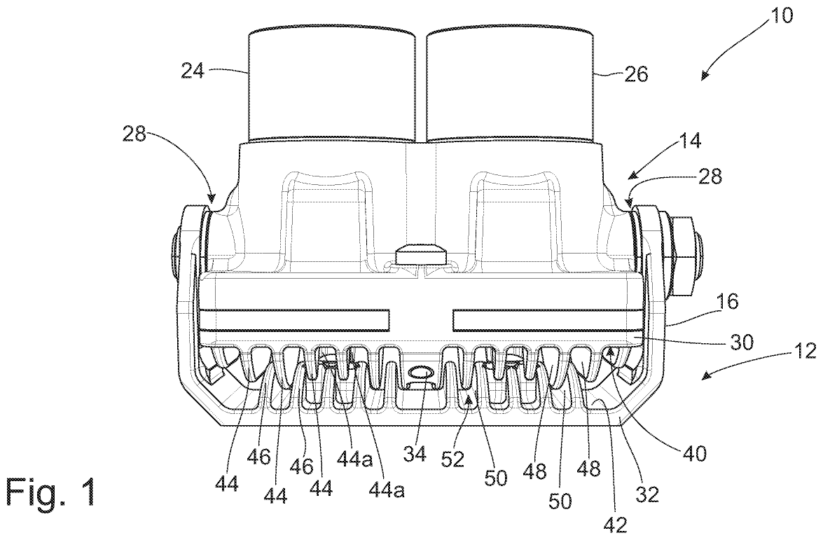

FIG. 1 shows a perspective view of an object detection sensor with a cooling device;

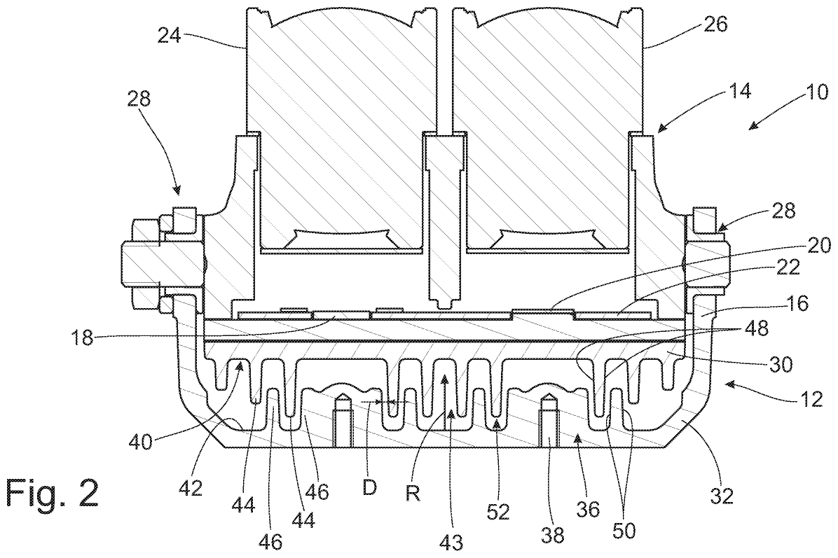

FIG. 2 shows a cross-sectional view of the object detection sensor with the cooling device of FIG. 1;

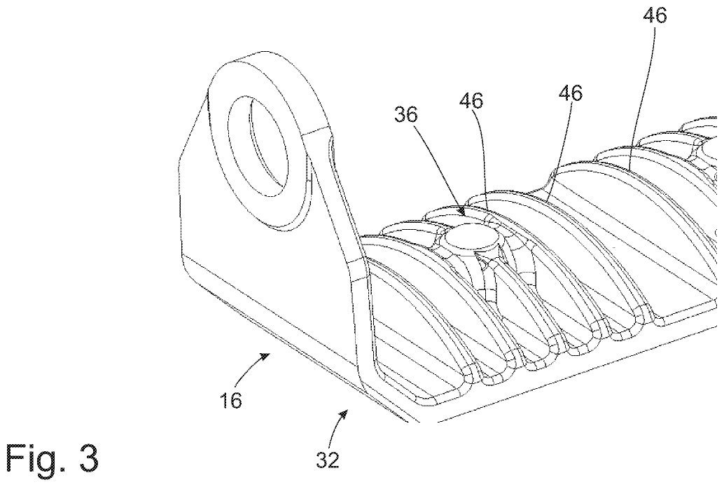

FIG. 3 shows a partial perspective view of a holding element of the object detection sensor with the cooling device from FIG. 1;

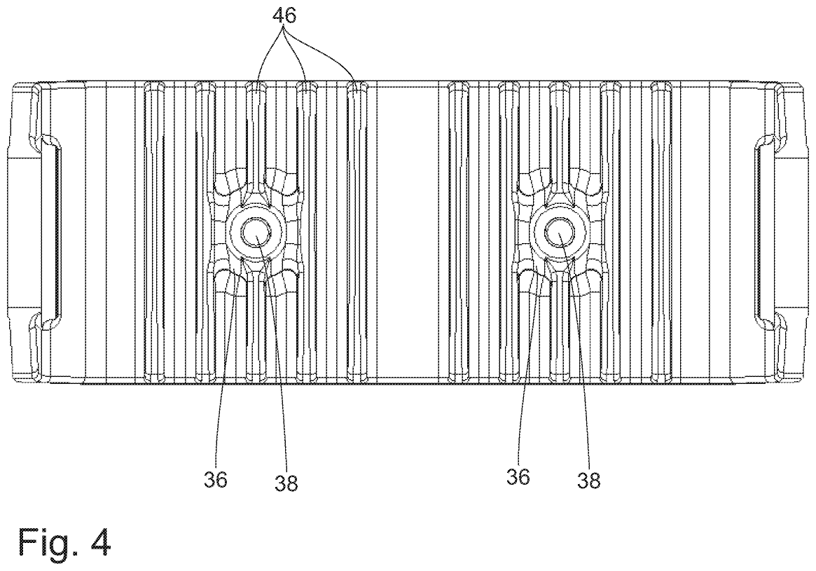

FIG. 4 shows the holding element from FIG. 3 in a front view.

FIG. 1 illustrates an object detection sensor 10 having a cooling device 12. The object detection sensor 10 comprises a multi-part housing 14 with the sensor components and a holding element 16 on which the multi-part housing 14 is arranged. In this case, the object detection sensor 10 is designed as a LIDAR system, which has a transmitting element 18 in the form of a transmitting chip, a receiving element 20 in the form of a receiving chip, and a main circuit board with further electronic components. Main circuit board 22. In addition, the object detection sensor 10 has an optical transmitting system 24 and an optical receiving system 26, each of which has an optics housing for arranging a plurality of optical elements. Optical transmitting system 24 and optical receiving system are shown in FIG. 2 only schematically and without further detail. The LIDAR system is designed particularly advantageously according to the LIDAR system published in patent specification WO 2017/081294 A1.

The multi-part housing 14 of the object detection sensor 10 is arranged to be pivotable relative to the holding element 16 via bearing elements 28. By pivoting, for example, a viewing area of the object detection sensor 10 can be aligned with a horizon to optimally adapt the field of vision to the environment.

During operation of the object detection sensor 10, the electronic components, in particular the transmitting element 18 and the receiving element 20, generate heat energy. This heat energy is dissipated from the object detection sensor via the cooling device 12.

The cooling device 12 comprises a heat transmission element 30 formed on the sensor side and a heat absorption element 32 formed distant from the sensor. The heat transmission element 30 is formed by a metal plate, in particular in the form of an aluminum plate, and is attached to the object detection sensor. In this case, the heat transmission element 30 is attached to the multi-part housing by means of a screw connection and forms part of the sensor housing. The screw connection is made by a screw which engages in an opening 34 having a thread.

The heat absorption element is formed by the holding element 16. In particular, the holding element has reinforcing structures 36. Openings 38 are incorporated in the reinforcing structures 36 on the holding element's 16 side opposite the object detection sensor. These openings 36, in particular drill holes, form a thread so that the object detection sensor can be attached.

The heat transmission element 30 has a heat transmission surface 40 which faces the heat absorption element 32. The heat absorption element 32, in turn, has a heat absorption surface 42 facing the heat transmission element. The heat transmission surface 40 and the heat absorption surface 42 face each other.

The cooling device 12 provides cooling by transferring heat energy generated by the electronics to the heat transmission element 30. The heat energy from the electronic components absorbed by the heat transmission element 30 is transferred to the heat absorption surface 42 via its heat transmission surface 40 by means of thermal radiation and is absorbed by the heat absorption element 32. The heat energy absorbed by the heat absorption element 32 is then released to the environment. In addition to transferring the heat energy by thermal radiation, the heat energy is also partially transferred by convection.

In particular, the heat absorption element 32 in the form of the holding element 16 is fixedly connected to a housing, in particular a module housing of the object detection sensor and the cooling device. Alternatively, the holding element 16 can also be integrally formed by the module housing. Such a module housing advantageously encloses the object detection sensor and the cooling device completely and in a fluid-tight manner.

The transfer of heat energy from the heat transmission element 30 to the heat absorption element 32 takes place in a non-contact manner via an intermediate space 43. The intermediate space 43 is formed between the heat transmission element 30 and the heat absorption element 32. The object detection sensor is formed such that the heat transmission element 32 and the heat absorption element 32 do not come into abutting contact. This enables frictionless and easy pivoting of the object detection sensor with respect to the holder. The intermediate space 43 provides a clearance between the heat transmission element and the heat absorption element.

In an alternative variant, a liquid, such as an oil or grease, can be disposed within the intermediate space 43 instead of a gas. Heat transfer then takes place through the thermal conductivity of the liquid.

A plurality of ribs projecting towards the opposite element are formed on each of the heat transmission element 30 and the heat absorption element 32. The ribs 44 of the heat transmission element are formed as semicircular discs extending in a direction R towards the heat absorption element 32. The direction R extends from the heat absorption element towards the heat transmission element 32. In particular, it is perpendicular to the associated surface portion as shown in FIG. 2. In addition, the heat absorption element also has ribs 46 which are also formed by semicircular discs and extend towards the heat transmission element 30.

At the heat absorption element 32, some of the ribs 46 transition into the reinforcing structure 36. Accordingly, the ribs 44 facing this reinforcing structure are provided with a recess 44a. This recess 44a is formed such that pivoting of the multi-part housing 14 at the desired pivot angle is still possible in a non-contact manner.

The ribs 44 and 46 greatly increase the heat transmission surface 40 and the heat absorption surface 42. In this case, each rib 44 of the heat transmission element 30 has two heat transmission undersurfaces 48 and each rib 46 of the heat absorption element 32 has two heat absorption undersurfaces 50.

Ribs 44 and 46 are arranged opposite to and offset from one another on the heat transmission element 30 and the heat absorption element 32 so that they engage with each other. Accordingly, between two ribs of the one element, one rib of the other element is disposed. In particular, the intermediate space 43 in the illustration of FIG. 2 extends through the ribs in a substantially meandering manner. Accordingly, the ribs 44 and 46 engage with each other alternately, in particular in a comb-shaped manner. Here, a heat transmission undersurface 48 is mostly associated with a heat absorption undersurface 50 of the adjacent rib. Between in each case two ribs of an element, a free space 52 is formed which is part of the intermediate space 43. In particular, a rib of the one element engages in a free space 52 of the other element.

The disc-shaped ribs are aligned in such a manner that pivoting of the multi-part housing 14 and thus of the sensor system relative to the holding element 16 is made possible. In particular, the opposing ribs do not make abutting contact with one another in any pivoted position. For this purpose, the ribs are formed in a direction of extent which is perpendicular to the direction R and perpendicular to a pivoting direction of the multi-part housing 14.

Between the ribs arranged opposite and adjacent to one another, a distance of the heat transmission undersurfaces of a few millimeters is possible. Such a distance D can be, for example, 0.5 millimeter, 1 millimeter or even two millimeters. In particular, distances in the range of 0.5 millimeters to 2 millimeters are possible. Such a small distance makes the transmission by thermal radiation particularly effective.

Furthermore, the ribs 46 and 44 are formed such that they overlap in the radial direction at least partially or to a large extent, thus, at least more than 50%, in the direction R. Alternatively, a heat transmission undersurface 48 and a heat absorption undersurface 50 can overlap over a portion or most of their surface area, thus, at least 50% of their surface area.

To further optimize heat transfer, the heat transmission element 30 and the heat transmission element 32, in particular the heat transmission surface 40 and the heat absorption surface 42, can be provided with an emission-optimized or absorption-optimized surface. This can be, for example, a coating, a varnish or even a specific texture of the surface.

Furthermore, when a gas is used within the intermediate space 43, it is also possible to form a fan which circulates the fluid and which circulates the fluid in intermediate space, thereby providing a higher heat transfer via convection.

1. A cooling device for an object detection sensor, comprising
a sensor-side heat transmission element
a sensor-distant heat absorption element
wherein the sensor-side heat transmission element and the sensor-distant heat absorption element are arranged opposite to one another, wherein
a heat transmission surface of the sensor-side heat transmission element and a heat absorption surface of the sensor-distant heat absorption element are designed to be spaced apart from one another by an intermediate space,
wherein the cooling device is designed to provide a relative movement between the heat transmission element and the heat absorption element, wherein the relative movement is a pivoting movement.

2. The cooling device according to claim 1, wherein the heat transmission element is formed by sensor housing of the object detection sensor or is connected to a sensor housing of the object detection sensor.

3. The cooling device according to claim 1, wherein the heat absorption element is formed by a holding element or is connected to a holding element.

4. (canceled)

5. The cooling device according to claim 1, wherein the heat transmission element and the heat absorption element have a distance to one another at each relative position so that there is no abutting contact between them.

6. The cooling device according to claim 1, wherein the heat transmission element and/or the heat absorption element have/has ribs.

7. The cooling device according to claim 1, wherein the ribs of the heat transmission element and the ribs of the opposite heat absorption element engage with one another.

8. The cooling device according to claim 1, wherein between two adjacent ribs of the heat transmission element or heat absorption element, a free space is formed in which a rib of the opposite heat absorption element or heat transmission element engages.

9. The cooling device according to claim 1, wherein the heat transmission element is in abutting contact with a circuit board and/or a chip of the object detection sensor.

10. The cooling device according to claim 1, wherein the heat transmission surface has a surface optimized for emission and/or the sensor-distant heat transmission surface has a surface optimized for absorption.

11. An object detection sensor comprising a cooling device for an object detection sensor,
said cooling device comprising:
a sensor-side heat transmission element; and
a sensor-distant heat absorption element;
wherein the sensor-side heat transmission element and the sensor-distant heat absorption element are arranged opposite to one another, wherein a heat transmission surface of the sensor-side heat transmission element and a heat absorption surface of the sensor-distant heat absorption element are designed to be spaced apart from one another by an intermediate space; and
wherein the cooling device is designed to provide a relative movement between the heat transmission element and the heat absorption element, wherein the relative movement is a pivoting movement.
